(19) United States
(12) Patent Application Publication
(10) Pub. No.: US 2026/0088758 A1
(43) Pub. Date: Mar. 26, 2026

(54) CRYSTAL UNIT WITH BUILT-IN TEMPERATURE SENSOR

(71) Applicant: NIHON DEMPA KOGYO CO., LTD., Tokyo (JP)

(72) Inventors: Akihiro SAKANASHI, Saitama (JP); Takumi ARIJI, Saitama (JP)

(73) Assignee: NIHON DEMPA KOGYO CO., LTD., Tokyo (JP)

(21) Appl. No.: 19/267,632

(22) Filed: Jul. 13, 2025

(30) Foreign Application Priority Data
Sep. 26, 2024 (JP) 2024-167745

(51) Int. Cl. H03B 5/04; H03H 9/19

(52) U.S. Cl. CPC H03B 5/04; H03H 9/19

(57) ABSTRACT

A crystal unit with a built-in temperature sensor includes an AT-cut quartz-crystal vibrating piece, a temperature sensor, a container, and a substrate. The container contains the AT-cut quartz-crystal vibrating piece and the temperature sensor. The substrate is not integral with the container and has a first principal surface with a first portion on which the container is connected using a conductive member. The temperature sensor is connected to a second portion other than the first portion on the first principal surface of the substrate via a conductive member. The quartz-crystal vibrating piece is connected to a second principal surface side portion on a second principal surface opposite to the first principal surface of the substrate across the substrate via a conductive member.

### CROSS-REFERENCE TO RELATED APPLICATIONS

This application is based on and claims priority under 35 U.S.C. § 119 to Japanese Patent Application No. 2024-167745, filed on Sep. 26, 2024, the entire content of which is incorporated herein by reference.

### TECHNICAL FIELD

This disclosure relates to a crystal unit having a built-in temperature sensor such as a thermistor.

### DESCRIPTION OF THE RELATED ART

In recent years, a crystal unit having an AT-cut quartz-crystal vibrating piece and a temperature sensor contained in a single container, so-called crystal unit with a built-in temperature sensor has been increasingly employed. The crystal unit of this type allows acquisition of a target frequency with higher accuracy since an external electronic device (chip set) designed on the premise of using such crystal unit compensates the oscillatory frequency of the quartz-crystal vibrating piece based on the temperature information detected by the temperature sensor.

A single chamber type of the crystal unit with a built-in temperature sensor has been known as one example. In other words, such crystal unit is produced by mounting the quartz-crystal vibrating piece and the temperature sensor in the single chamber, and sealing the chamber air-tightly (for example, see Japanese Unexamined Patent Application Publications No. 2015-226152 and No. 2023-135986).

Japanese Unexamined Patent Application Publication No. 2015-226152 discloses that the temperature sensor is mounted on the region between a pair of connection pads on which the quartz-crystal vibrating piece is mounted in the container (see abstract and the like in the document). Japanese Unexamined Patent Application Publication No. 2023-135986 discloses that the resonator is provided on the first portion of the support projecting from the inner wall of the container, and the temperature sensor is provided on the second portion opposite to the first portion in the thickness direction of the support (see abstract and the like in the document).

In either case, since the temperature sensor and the quartz-crystal vibrating piece can be easily placed in close proximity, it is possible to reduce the temperature difference between the temperature sensor and the quartz-crystal vibrating piece (see abstracts and the like in those documents). Reduction in the temperature difference between the temperature sensor and the quartz-crystal vibrating piece is advantageous as a measure for improving the temperature compensation accuracy.

However, in the structure as disclosed in Japanese Unexamined Patent Application Publication No. 2015-226152, the distance between the paired connection pads is narrow, and miniaturization of the temperature sensor is limited. Accordingly, it is realistically difficult to mount the temperature sensor between the paired connection pads in the container.

Furthermore, in the structure as disclosed in Japanese Unexamined Patent Application Publication No. 2023-135986, the support horizontally projects from the inner wall of the package and is integrated with the container. It is therefore realistically difficult to provide the quartz-crystal vibrating piece on the first surface and the temperature sensor on the second surface of the support.

A need thus exists for a crystal unit with a built-in temperature sensor, which is not susceptible to the drawback mentioned above.

### SUMMARY

According to an aspect of this disclosure, there is provided a crystal unit with a built-in temperature sensor that includes an AT-cut quartz-crystal vibrating piece, a temperature sensor, a container, and a substrate. The container contains the AT-cut quartz-crystal vibrating piece and the temperature sensor. The substrate is not integral with the container and has a first principal surface with a first portion on which the container is connected using a conductive member. The temperature sensor is connected to a second portion other than the first portion on the first principal surface of the substrate via a conductive member. The quartz-crystal vibrating piece is connected to a second principal surface side portion on a second principal surface opposite to the first principal surface of the substrate across the substrate via a conductive member.

According to the aspect of this disclosure, the quartz-crystal vibrating piece and the temperature sensor opposed to one another across the substrate in the thickness direction of the substrate. The thermal conduction to the quartz-crystal vibrating piece and the temperature sensor by way of an object occurs through the common substrate from substantially the common positions of the substrate. Accordingly, the quartz-crystal vibrating piece and the temperature sensor may be in a common thermal environment except the difference in specific heat. This makes it possible to reduce the temperature difference between the quartz-crystal vibrating piece and the temperature sensor.

As the substrate is not integral with the container, an arbitrary material can be selected for forming the substrate. For example, it is possible to select the substrate with desired thermal conductivity, or the substrate with desired thermal expansion coefficient.

As the substrate is not integral with the container, the crystal unit with a built-in temperature sensor can be manufactured using the realistic method implemented by, for example, mounting the temperature sensor on the first principal surface of the substrate, then mounting such substrate in the container, and subsequently mounting the quartz-crystal vibrating piece on the second principal surface of the substrate.

This makes it possible to provide the crystal unit with a built-in temperature sensor having a realistically novel structure that allows reduction in the temperature difference between the temperature sensor and the quartz-crystal vibrating piece.

### BRIEF DESCRIPTION OF THE DRAWINGS

The foregoing and additional features and characteristics of this disclosure will become more apparent from the following detailed description considered with reference to the accompanying drawings, wherein:

FIG. 1A to FIG. 1C are explanatory drawings of a crystal unit 10 with a built-in temperature sensor according to an embodiment disclosed here;

FIG. 2A to FIG. 2C are explanatory drawings of the crystal unit 10 with a built-in temperature sensor, especially, details of a substrate according to an embodiment disclosed here;

FIG. 3A and FIG. 3B are explanatory drawings of a preferred example of the quartz-crystal vibrating piece when using a substrate formed of a crystal disclosed here;

FIG. 4A and FIG. 4B are explanatory drawings of a preferred example with respect to a relationship between a temperature sensor thickness and a recess portion of a container, a substrate length, and a width of a recess portion disclosed here; and

FIG. 5A to FIG. 5C are explanatory drawings of specific examples of a quartz-crystal vibrating piece disclosed here.

### DETAILED DESCRIPTION

An embodiment disclosed here will be explained with reference to the drawings. Each drawing used in the description is merely illustrated schematically for understanding this disclosure. In each drawing used in the description, like reference numerals designate corresponding or identical elements, and therefore such elements may not be further elaborated here. Structure examples, and members used described in the following explanations are merely preferred examples within the scope of this disclosure. Therefore, this disclosure is not limited only to the following embodiment.

### 1. Crystal Unit According to Embodiment

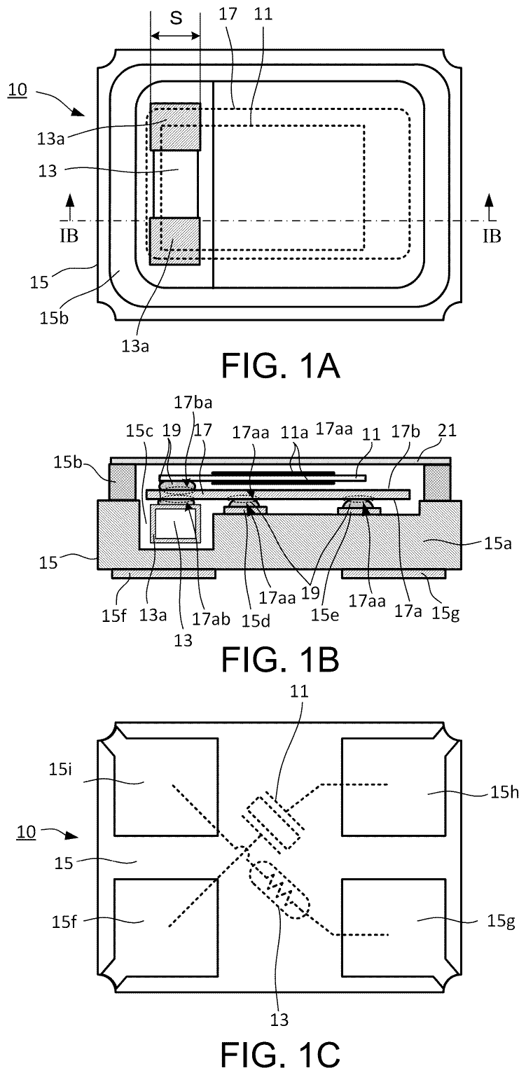

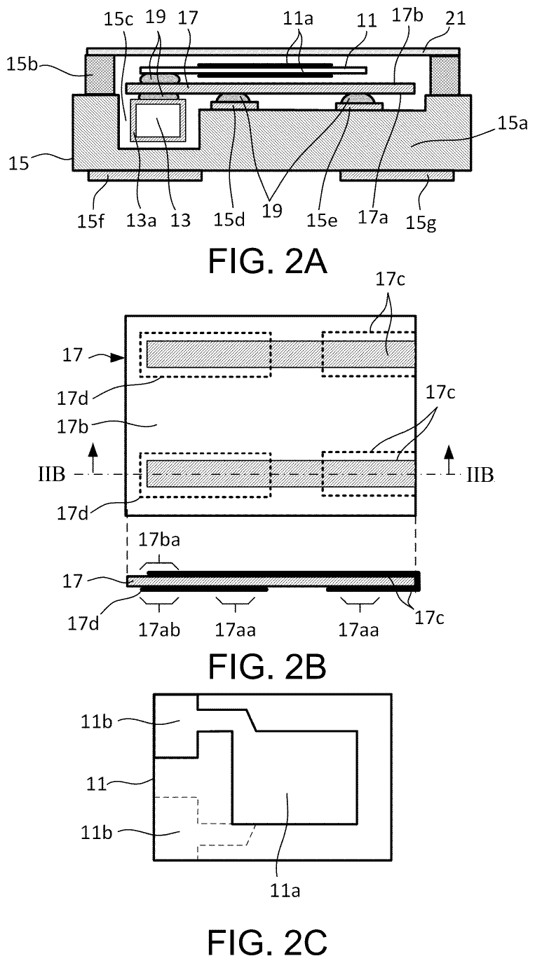

FIG. 1A to FIG. 1C, and FIG. 2A to FIG. 2C are explanatory drawings of a crystal unit 10 with a built-in temperature sensor (hereinafter also referred to as a crystal unit 10) according to an embodiment. Specifically, FIG. 1A is a top view of the crystal unit 10, FIG. 1B is a sectional view taken along the line IB-IB of FIG. 1A, and FIG. 1C is a bottom view. FIG. 1A illustrates a state in which a lid member 21 is removed. FIG. 2A to FIG. 2C are explanatory drawings illustrating a relationship between a quartz-crystal vibrating piece 11 and a substrate 17. Especially, FIG. 2B includes a top view of the substrate 17, and a cross-sectional view taken along the line IIB-IIB in the top view.

The crystal unit 10 includes an AT-cut quartz-crystal vibrating piece 11, a temperature sensor 13, a container 15 that contains the quartz-crystal vibrating piece 11 and the temperature sensor 13, and a predetermined substrate 17. The predetermined substrate 17 is not integral with the container 15 and has a first portions 17aa on a first principal surface 17a connected to the container 15 using conductive members 19.

The temperature sensor 13 is connected to a second portion 17ab, other than the first portions 17aa, on the first principal surface 17a of the substrate 17 via the conductive member 19. The quartz-crystal vibrating piece 11 is connected to a second principal surface side portion (opposite portion) 17ba on a second principal surface 17b opposite to the first principal surface 17a of the substrate 17 across the substrate 17 via the conductive member 19. The container 15 is sealed with the lid member 21. The respective components will be described in detail hereinafter.

As illustrated especially in FIG. 2C, the AT-cut quartz-crystal vibrating piece 11 has a quadrangular planar shape, specifically, a rectangular shape in this example. The quartz-crystal vibrating piece 11 with a predetermined thickness in accordance with an oscillatory frequency includes excitation electrodes 11a on the principal surfaces on both sides, and extraction electrodes 11b extracted from the excitation electrodes 11a to one short side of the quartz-crystal vibrating piece.

The quartz-crystal vibrating piece 11 adapted to the design of the crystal unit is selected from the quartz-crystal vibrating piece of so-called X-long type, having its long side parallel to an X-axis as a crystallographic axis of a crystal, and its short side parallel to a Z′-axis as a crystallographic axis of a crystal, the quartz-crystal vibrating piece of so-called Z-long type, having its long side parallel to the Z′-axis of the crystal, and its short side parallel to the X-axis of the crystal, or the quartz-crystal vibrating piece of type with a quadrangular planar shape having one side parallel to either the X-axis or the Z′-axis of the crystal. The planar shape of the quartz-crystal vibrating piece 11 is not limited to the quadrangular shape, but may be an arbitrary shape such as a circular shape and an elliptical shape.

It is preferable to employ a thermistor for the temperature sensor 13. However, the temperature sensor 13 is not limited to a thermistor; it is also possible to employ another device, such as a diode. This is because a temperature sensor can be realized by utilizing the temperature dependence of the PN junction of a diode. In this example, the temperature sensor 13 with a rectangular parallelepiped shape includes connection terminals 13a at both ends in the longitudinal direction. However, the temperature sensor 13 is not limited to the above example and may also have another configuration, such as a thin-film thermistor.

Preferably, a portion of the temperature sensor 13 except its portion connected to the substrate 17 is not in contact with other members. In this example, preferably, the portion of the temperature sensor 13 except its portion connected to the substrate 17 is not in contact with an inner wall of a recess portion 15c formed in a base 15a of the container 15 to allow only the substrate 17 to serve as a solid thermal conduction path to the temperature sensor 13.

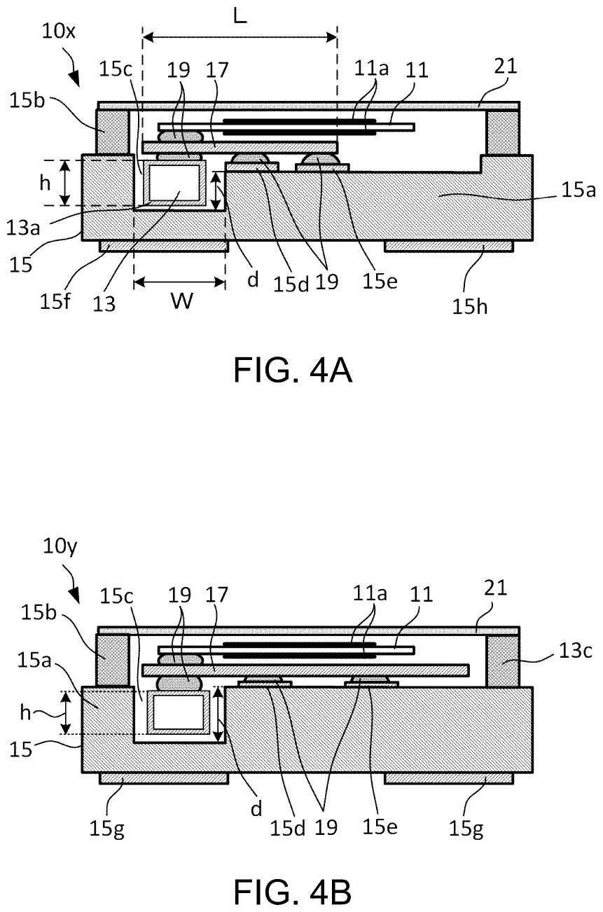

In this case, the container 15 has a quadrangular planar shape, specifically, it is formed into a rectangular ceramic package. The container 15 includes the base 15a, a bank portion 15b formed along an edge of the base 15a, and the recess portion 15c that is formed in the base 15a, and allowed to planarly contain the temperature sensor 13. The quartz-crystal vibrating piece 11 and the temperature sensor 13 are contained in the space surrounded by the base 15a and the bank portion 15b. In this example, the temperature sensor 13 is contained in the recess portion 15c. The recess portion 15c in this example has its depth sufficient to contain the temperature sensor 13 entirely or partially in the height direction, and is formed at a portion corresponding to one inner end of the container 15, that is, the portion closer to the bank portion 15b. A preferred example with respect to the relationship between the recess portion 15c and the temperature sensor 13 will be described later with reference to FIG. 4A and FIG. 4B.

Connection pads 15d, 15e for connecting the substrate 17 are provided on a region of the base 15a. In this example, the connection pad 15d corresponds to the temperature sensor 13. The connection pad 15e corresponds to the quartz-crystal vibrating piece 11. That is, the connection pads 15d, 15e are connected to the quartz-crystal vibrating piece 11 and the temperature sensor 13 in a predetermined relationship via connection wirings 17c, 17d provided on the substrate 17.

External connection terminals 15f, 15g, 15h, 15i for connecting the crystal unit 10 to an electronic substrate for an arbitrary electronic device, for example, a mobile phone are provided at four corners on an outer bottom surface of the container 15, respectively (see FIG. 1C). The connection pads 15d and the connection pad 15e are electrically connected to the external connection terminals 15f, 15g, 15h, 15i in a predetermined relationship using a not shown via wiring or castration wiring.

A top surface of the bank portion 15b of the container 15 is treated adaptively to the sealing method. Specifically, when the sealing method is a seam-sealing method, a seam ring (not shown) is provided on the top surface of the bank portion 15b.

The substrate 17 intervening among the container 15, the quartz-crystal vibrating piece 11, and the temperature sensor 13 serves as a base common to the quartz-crystal vibrating piece 11 and the temperature sensor 13.

Although not limited, it is preferable to use the substrate 17 having a quadrangular planar shape because of easy processing of the substrate. The substrate 17 can be formed of an arbitrarily suitable material. For example, the substrate may be formed using glass material, ceramic material, resin material, or crystal material. When it is desired to promote heat transfer from the container 15 to the quartz-crystal vibrating piece 11 and the temperature sensor 13, a substrate made of a material having high thermal conductivity may be selected. On the other hand, when it is desired to suppress heat transfer, a substrate made of a material having low thermal conductivity may be selected. Furthermore, it is also possible to employ the crystal substrate adapted to the thermal expansion coefficient of the quartz-crystal vibrating piece 11. A description will be made later concerning an appropriate example considering the crystallographic axis of a crystal when employing the crystal substrate for the substrate 17.

Preferably, the substrate 17 has its thickness set in consideration of the thermal conductivity, and the influence of stress on the quartz-crystal vibrating piece. When the thickness of the substrate 17 is too small, strength of the substrate cannot be secured. When the thickness of the substrate 17 is too large, it will influence the thickness of the entire structure of the crystal unit 10. Accordingly, it is possible to set the thickness in the range from 30 to 100 μm, and preferably, from 40 to 70 μm. Alternatively, it is still possible to further reduce the thickness. The substrate may be formed by using a plurality of substrates, each of which is formed of the different material without limiting the use of the single substrate.

The planar size of the substrate 17 is set such that it can be contained in the container 15. Although not specifically limited, in this example, the planar size of the substrate 17 is larger than that of the quartz-crystal vibrating piece 11. Other examples will be described later with reference to FIG. 4A and FIG. 4B.

It is preferable to perform allocation of an area of the substrate 17 to the first portion 17aa, the second portion 17ab, and the second principal surface side portion (opposite portion) 17ba as described below.

Preferably, considering efficient use of the substrate 17, the second portion 17ab has an area for connection of the temperature sensor 13 is positioned at one end side of the substrate 17 to have a width that allows connection to the temperature sensor 13 from the end of the substrate 17. Specifically, if the temperature sensor 13 has a rectangular parallelepiped shape, so-called 0603 type, the temperature sensor 13 has its width of 0.3 mm. Accordingly, it is preferable that the second portion 17ab has an area with a length of approximately 0.3 mm from the end of the substrate 17. In a general case, assuming that the width of the temperature sensor 13 is defined as S (see FIG. 1A), it is preferable that the second portion 17ab has a length ranging from 0.8 S to 1.5 S from the end of the substrate 17, preferably, from 0.8 S to 1.2 S from the end of the substrate 17, and further preferably, from 0.9 S to 1.2 S from the end of the substrate 17.

Preferably, the second principal surface side portion (opposite portion) 17ba opposite to the second portion 17ab has the area that is wide enough to support the quartz-crystal vibrating piece 11, specifically, substantially as wide as the support portion of the quartz-crystal vibrating piece 11. Alternatively, although not limited to the one as described above, similarly to the second portion 17ab, it is preferable that the second principal surface side portion 17ba has the area with a length ranging from 0.8 S to 1.5 S, and more preferably, from 0.8 S to 1.2 S from the end of the substrate 17. In this example, the area of the second portion 17ab is defined using the width S of the temperature sensor. When the temperature sensor is more compact, and has its long side dimension smaller than that of the fixed area of the quartz-crystal vibrating piece 11, the S may be defined as the long side dimension.

Meanwhile, the first portions 17aa secure an area sufficient to have the connection wiring 17d (see FIG. 2B) from the temperature sensor 13, and an area sufficient to have the connection wiring 17c (see FIG. 2B) from the quartz-crystal vibrating piece 11, respectively, and further secure an area that allows connection of the substrate 17 to the container 15 while keeping the desired strength. For example, in view of the width S of the temperature sensor, it is preferable that the first portion 17aa has a length ranging from 1.5 S to 3 S, more preferably, from 1.5 S to 2.5 S, and further preferably, from 1.5 S to 2 S from an end of the second portion 17ab. In this example, areas corresponding to the first portions 17aa are connected to a total of four connection pads including the connection pads 15d for the quartz-crystal vibrating piece 11, and the connection pads 15e for the temperature sensor 13.

As illustrated in FIG. 2B, for electrical connection among the quartz-crystal vibrating piece 11, the temperature sensor 13, and the container 15, the substrate 17 includes the predetermined connection wirings 17c, 17d on the first principal surface 17a and the second principal surface 17b, respectively. That is, the connection wiring 17c for connecting the quartz-crystal vibrating piece 11 to the connection pad 15e in the container is provided over a region from the first principal surface 17a to the second principal surface 17b of the substrate 17, and the connection wiring 17d for connecting the temperature sensor 13 to the connection pad 15d is provided on the first principal surface 17a of the substrate 17.

For the conductive member 19, it is possible to use various types of conductive adhesives, for example, a silicone-based conductive adhesive, an epoxy-based conductive adhesive, and polyimide-based conductive adhesive, or the material other than the adhesive, for example, a metal bump. It is preferable to use the silicone-based conductive adhesive from an aspect of functions of thermal stress relief and impact absorption. The conductive member used between the substrate 17 and the temperature sensor 13 may be either the same as or different from the conductive member to be used between the substrate 17 and the quartz-crystal vibrating piece 11. It is preferable to use the same conductive members.

The lid member 21 may be of arbitrary type in accordance with the sealing method. When the seam sealing is used as the sealing method, the lid member 21 may be formed of, for example, a nickel-plated kovar material.

In the crystal oscillator 10 of the embodiment, the quartz-crystal vibrating piece 11 and the temperature sensor 13 are arranged in a state of being closely opposed to each other with the substrate 17 interposed in the thickness direction. Accordingly, heat is conducted to the quartz-crystal vibrating piece and the temperature sensor by way of an object via the substrate 17 from substantially common positions on the substrate, that is, the second portion 17ab and the second principal surface side portion (opposite portion) 17ba of the substrate 17. This makes it possible to reduce the temperature difference between the quartz-crystal vibrating piece and the temperature sensor. Furthermore, since the substrate 17 is not integral with the container 15, the substrate 17 may be formed of an arbitrary material. Furthermore, the substrate 17 that is not integral with the container 15 allows manufacturing of the crystal unit with a built-in temperature sensor using the realistic method implemented by, for example, mounting the temperature sensor 13 on the first principal surface 17a of the substrate 17, mounting such substrate 17 in the container 15, and mounting the quartz-crystal vibrating piece 11 on the second principal surface 17b of the substrate 17.

### 2. Preferred Example of Using Crystal Substrate 17

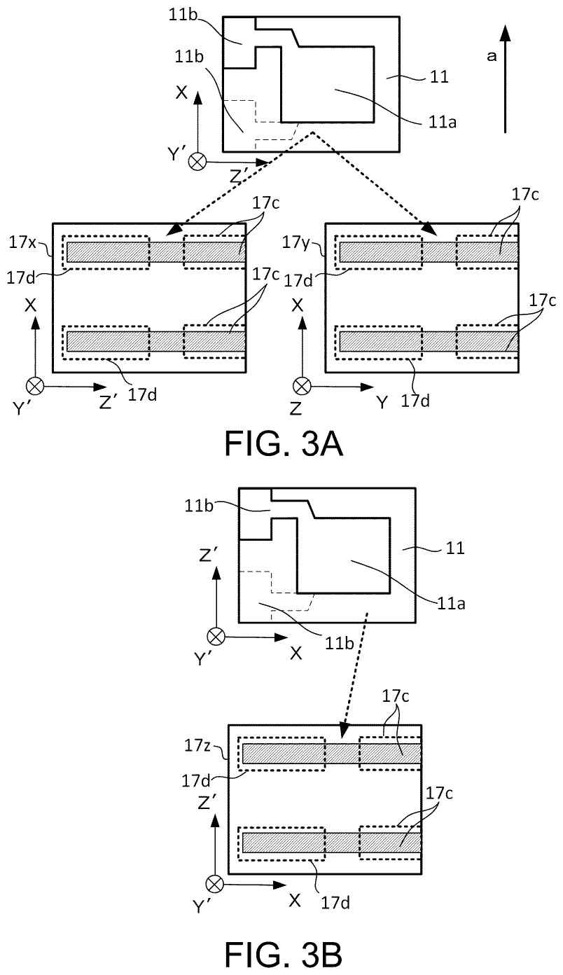

In the above description, an arbitrary material can be used for forming the substrate 17. It is preferable, however, to use the substrate 17 formed of crystal in consideration of adaptability to the thermal expansion coefficient of the quartz-crystal vibrating piece 11. It is further preferable to place the quartz-crystal vibrating piece 11 and the crystal substrate 17 in an arrangement considering the crystallographic axis of a crystal. An example of using the crystal substrate will be described with reference to FIG. 3A and FIG. 3B.

FIG. 3A illustrates a case in which the quartz-crystal vibrating piece 11 is connected to a substrate 17x or 17y at two positions along an X-axis of a crystal. That is, two extraction electrodes 11b exist at two positions, which are distant from each other along the X-axis of the crystal of the quartz-crystal vibrating piece 11. The quartz-crystal vibrating piece 11 is bonded to the substrates 17x, 17y at those positions. Specifically, an example of the lower left section in FIG. 3A illustrates the substrate 17x formed of the AT-cut crystal element, having the connection wirings 17c, 17d at two positions, respectively, along the X-axis of the crystal. An example of the lower right section in FIG. 3A illustrates the substrate 17y formed of a Z-cut quartz-crystal crystal element, having the connection wirings 17c, 17d at two positions, respectively, along a Z′-axis of the crystal.

The quartz-crystal vibrating piece 11 and the substrate 17x or the substrate 17y are arranged such that the X-axes of the respective crystals are positioned parallel to a first direction a (see FIG. 3A), in other words, matching with each other. The “matching” implies not only the case of exact matching, but also the case of a little misalignment within a scope of the disclosure (the same applied hereafter). The Z′-axis of the crystal as illustrated in FIG. 3A indicates an axis deviating from the true Z-axis of the crystal because of the cutting angle of the AT-cut crystal element (the same applied hereafter).

FIG. 3B illustrates an example of a case in which the quartz-crystal vibrating piece 11 is connected to a substrate 17z at two positions along the Z′-axis of the crystal. In this case, the substrate 17z includes the Z-axis or Z′-axis of the crystal in the plane and allows the quartz-crystal vibrating piece 11 to be connected at two positions along the Z-axis or the Z′-axis. Specifically, the substrate 17z is formed of the AT-cut crystal element, and includes the connection wirings 17c, 17d along the Z′-axis of the crystal of the substrate 17z corresponding to the extraction electrodes 11b of the quartz-crystal vibrating piece 11.

The quartz-crystal vibrating piece 11 and the substrate 17z are placed in an arrangement such that Z′-axes of the respective crystals are parallel to the first direction a (see FIG. 3A), in other words, matching with each other.

It should be noted that Table 2 and the relevant descriptions in applications JPA 2014-72182, and JPA 2024-154016 based on JPA 2014-72182 as the earlier application, which have been filed by the present applicant disclose details of the preferred use of the crystal substrate for matching crystallographic axes of the quartz-crystal vibrating piece and the crystal substrate.

### 3. Depth of Recess Portion for Mounting Temperature Sensor and the Like

The following describes a preferred example with respect to a relationship between a height h of the temperature sensor 13 and a depth d of the recess portion formed in the container 15 for temperature sensor, the substrate length, and a width of the recess portion. The examples will be described with reference to FIG. 4A, FIG. 4B. Each drawing of FIG. 4A and FIG. 4B corresponds to the sectional view in FIG. 1B.

With reference to a crystal unit 10x as illustrated in FIG. 4A, the relationship between the depth d of the recess portion 15c for mounting the temperature sensor 13 and the height h of the temperature sensor 13 is expressed by d≤hs.

In the case of the crystal unit 10x, since the relationship of d≤hs, as it is, the substrate 17 would come into direct contact with the container 15, and the temperature sensor 13 would touch the bottom surface of the recess portion 15c. The contact of the temperature sensor 13 with the bottom surface of the recess portion 15c is not preferable because such contact causes the thermal conduction path to the temperature sensor 13 to be different from the thermal conduction path to the quartz-crystal vibrating piece 11. In order to avoid such difference, each thickness of the connection pads 15d, 15e, and the conductive member 19 is set to an appropriate value. The relationship of d≤hs is likely to reduce the entire thickness of the crystal unit 10x.

With reference to a crystal unit 10y as illustrated in FIG. 4B, the relationship between the depth d of the recess portion 15c for mounting the temperature sensor 13 and the height h of the temperature sensor 13 is expressed by d>h.

In the case of the crystal unit 10y, the relationship of d>h attains higher degree of freedom for setting each thickness of the connection pads 15d, 15e, and the conductive member 19. This allows the crystal unit 10y to be manufactured more easily than manufacturing of the crystal unit 10x.

In both cases as illustrated in FIG. 4A or FIG. 4B, it is preferable to make a length L of the substrate 17 along the long side direction of the quartz-crystal vibrating piece 11 as small as possible in a range that secures an adhesive area in which the substrate 17 is connected to the container 15, and an adhesive area in which the quartz-crystal vibrating piece 11 and the temperature sensor 13 are connected to the substrate 17. The length L of the substrate 17 shorter than the length of the quartz-crystal vibrating piece 11 provides advantages of, for example, reduction in the risk of bringing a tip end of the quartz-crystal vibrating piece 11 into contact with the substrate 17, and reduction in the influence of stray capacitance on the excitation electrode 11a of the quartz-crystal vibrating piece 11.

It is preferable to make a width W of the recess portion 15c as wide as possible in a range that secures an adhesive area in which the substrate 17 is connected to the container 15, and an area in which the connection pads 15d, 15e are provided in a region of the container 15 besides the recess portion 15c. This makes it possible to mount the substrate 17 connected to the temperature sensor 13 in the container 15 more easily.

### 4. Quartz-Crystal Vibrating Piece

In the example as described above, the quartz-crystal vibrating piece 11 has a uniform thickness, and a rectangular planar shape. The shape of the quartz-crystal vibrating piece 11, however, is not limited to the one as described above.

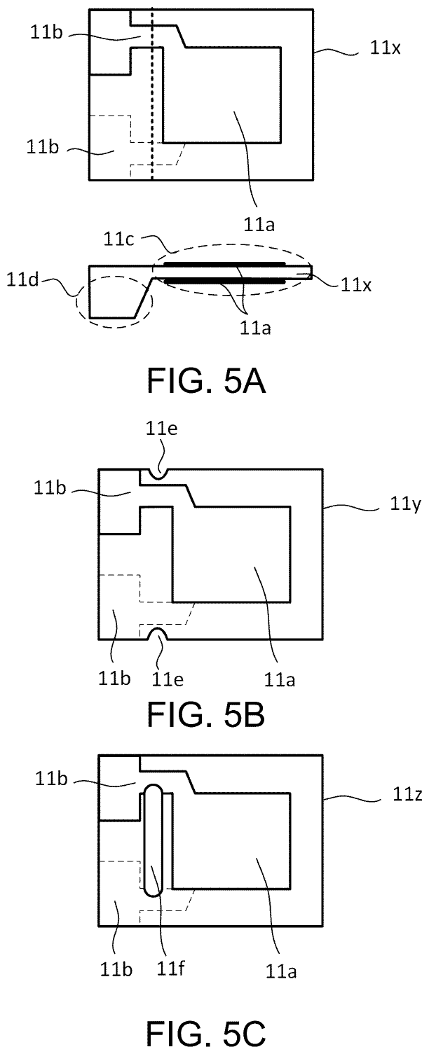

For example, as illustrated in FIG. 5A, the quartz-crystal vibrating piece may be structured into a shape of a frame corner part, which is composed of a resonator portion 11c with its thickness suitable for the frequency, and a support 11d with its thickness larger than that of the resonator portion 11c. As illustrated in FIG. 5B, the quartz-crystal vibrating piece may be structured to have a notch 11e formed between the resonator portion and the support of the quartz-crystal vibrating piece. As illustrated in FIG. 5C, the quartz-crystal vibrating piece may be structured to have a through hole 11f formed between the resonator portion and the support of the quartz-crystal vibrating piece. The notch 11e and the through hole 11f may be formed in the quartz-crystal vibrating piece with uniform thickness, or in the quartz-crystal vibrating piece structured into the shape of the frame corner part as illustrated in FIG. 5A.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A crystal unit with a built-in temperature sensor, comprising:
an AT-cut quartz-crystal vibrating piece;
a temperature sensor;
a container that contains the AT-cut quartz-crystal vibrating piece and the temperature sensor; and
a substrate that is not integral with the container and has a first principal surface with a first portion on which the container is connected using a conductive member, wherein
the temperature sensor is connected to a second portion other than the first portion on the first principal surface of the substrate via a conductive member, and
the quartz-crystal vibrating piece is connected to a second principal surface side portion on a second principal surface opposite to the first principal surface of the substrate across the substrate via a conductive member.

2. The crystal unit with a built-in temperature sensor according to claim 1, wherein,
the substrate is made of glass material, ceramic material, resin material, or crystal material, and
the quartz-crystal vibrating piece has a quadrangular planar shape, and is connected to the substrate using the conductive member while being cantilever supported at two positions along one side at a side closer to the one side of the quadrangular shape.

3. The crystal unit with a built-in temperature sensor according to claim 1, wherein,
the quartz-crystal vibrating piece has a quadrangular planar shape, and is connected to the substrate using the conductive member while being cantilever supported at two positions along one side at a side closer to the one side along an X-axis of a crystal, and
the substrate is formed of an AT-cut crystal plate or a Z-cut crystal plate, and arranged to have an X-axis of a crystal of the substrate matched with the X-axis of the quartz-crystal vibrating piece.

4. The crystal unit with a built-in temperature sensor according to claim 1, wherein,
the quartz-crystal vibrating piece has a quadrangular planar shape, and is connected to the substrate using the conductive member while being cantilever supported at two positions along one side at a side closer to the one side along a Z′-axis of a crystal,
the substrate is formed of an AT-cut crystal plate, and arranged to have a Z′-axis of a crystal of the substrate matched with the Z′-axis of the quartz-crystal vibrating piece.

5. The crystal unit with a built-in temperature sensor according to claim 1, wherein
a portion of the temperature sensor except a portion connected to the substrate is not in contact with other members.

6. The crystal unit with a built-in temperature sensor according to claim 1, wherein,
the container includes a recess portion capable of planarly containing the temperature sensor, and
the substrate is connected to the container to allow the temperature sensor connected to the substrate to be contained in the recess portion entirely or partially in a height direction of the temperature sensor.

7. The crystal unit with a built-in temperature sensor according to claim 1, wherein,
the container includes a recess portion in which the temperature sensor is mounted,
the substrate is connected to the container to allow the temperature sensor connected to the substrate to be contained in the recess portion entirely or partially in a height direction of the temperature sensor, and
a relationship between a depth d of the recess portion and a height h of the temperature sensor is expressed by d≤h.

8. The crystal unit with a built-in temperature sensor according to claim 1, wherein,
the container includes a recess portion in which the temperature sensor is mounted,
the substrate is connected to the container to allow the temperature sensor connected to the substrate to be contained in the recess portion entirely or partially in a height direction of the temperature sensor; and
a relationship between a depth d of the recess portion and a height h of the temperature sensor is expressed by d≥h.

9. The crystal unit with a built-in temperature sensor according to claim 1, wherein,
the substrate has a rectangular planar shape, and
when a width of the temperature sensor is defined as S, the second portion has an area at a side closer to one end of the substrate in a long side direction with a length ranging from 0.8 S to 1.5 S from the one end.

10. The crystal unit with a built-in temperature sensor according to claim 9, wherein
when the width of the temperature sensor is defined as S, the first portion has an area at a side closer to the other end of the substrate in the long side direction with a length ranging from 1.5 S to 3 S from the end of the second portion.
